(19) United States
(12) Patent Application Publication
(10) Pub. No.: US 2012/0175745 A1
(43) Pub. Date: Jul. 12, 2012

(54) METHODS FOR FABRICATING SEMICONDUCTOR DEVICES AND SEMICONDUCTOR DEVICES USING THE SAME

(75) Inventors: Pin Yuan Su, Taoyuan County (TW); Weitung Yang, Taoyuan County (TW); Yu-Chung Fang, Taoyuan County (TW)

(73) Assignee: NANYA TECHNOLOGY CORPORATION, Taoyuan (TW)

(21) Appl. No.: 12/986,147

(22) Filed: Jan. 6, 2011

(51) Int. Cl. H01L 29/06; H01L 21/306; H01L 21/308

(52) U.S. Cl. 257/622; 438/702; 438/692; 257/E21.231; 257/E21.23; 257/E29.022

(57) ABSTRACT

A method for fabricating a fine pattern of a semiconductor device is provided. The method includes forming a base layer, a first mask pattern having identical features of a first width with inclined sidewalls and a second mask pattern having identical features of a second width in sequence on a substrate, wherein a smallest distance between any two adjacent inclined sidewalls is equal to the second width. The base layer is etched by using the first mask pattern as an etch mask to form first openings of the second width and a fill layer is formed covering the substrate. The second mask pattern is removed to form second openings in the fill layer and then the first mask pattern and the base layer are etched through the second openings to form third openings. The fill layer and the first mask pattern are removed to form a pattern of the base layer having identical features of a third width, wherein the third width of the features of the base layer pattern is equal to the second width.

### BACKGROUND OF THE INVENTION

1. Field of the Invention

The invention relates to a method for fabricating a semiconductor device and more particularly to a method for fabricating a fine pattern of a semiconductor device using an advanced double patterning process.

2. Description of the Related Art

In order to integrate more elements in a narrower area, the size of a discrete element may be reduced. Miniaturization of a pattern in semiconductor device fabrication is necessary for higher integration of a semiconductor device. Recently, semiconductor device manufacturing techniques have continued to be developed and improved to reduce the pitch of a pattern, which is the sum of the width of a basic feature of the pattern and the width of the gap between two adjacent features.

Photolithography is one of the techniques used to manufacture highly integrated semiconductor devices. Currently, the smallest pitch of a pattern that can be transcribed onto a substrate using photolithography techniques has reached a limitation due to the limited resolution which can be achieved using photolithography. In forming semiconductor devices, it is difficult to form line/space patterns of 50 nm or less in size in a single exposure process using 1.0 or less numerical aperture (NA) ArF exposure equipment; even when employing an immersion lithography process.

To improve resolution in photolithography processes and increase process margins, various pattern formation techniques have been proposed in order to overcome the resolution limitation of the photolithography process. In a conventional double patterning process, a fine pattern is obtained by a double exposure process to expose a pattern twice. The conventional double patterning process involves exposing and etching a first pattern having a space that is twice a desired space, and then exposing and etching a second pattern having the same space between the features of the first pattern. Because the degree of overlay between the second exposing process and the first exposing process is difficult to control accurately for the overall wafer, critical dimension (CD) uniformity of the fine pattern of the semiconductor devices is poor when using the conventional double patterning process.

In another conventional double patterning process, first, a patterned mask of repeated features is formed using a photolithography process. These features are spaced at a pitch that is large due to the limited resolution of the photolithography process. Next, spacers are formed on opposite sides of each feature. Then, a layer underlying the patterned mask is etched using the spacers and the repeated features together as a hard mask to form a fine pattern. However, the spacers are often formed unevenly on the sides of each feature. Thus, critical dimensions (CD) and CD uniformity of the fine pattern are difficult to control in the overall wafer by the conventional double patterning process. Further, in the conventional double patterning process, the spacers must be removed after using them as a hard mask. Thus, this technique increases the number of process steps needed and production costs.

Therefore, an advanced double patterning process for fabrication of a fine pattern of a semiconductor device which overcomes the above problems is desired.

### BRIEF SUMMARY OF THE INVENTION

Methods for fabricating a fine pattern of a semiconductor device are provided. According to the methods of the present disclosure, the critical dimensions (CD) of the fine pattern are shrunk without a spacer liner deposition process and without a spacer etching process. Moreover, according to the methods of the present disclosure, the critical dimensions (CD) of the fine pattern are controlled accurately and CD uniformity of the fine pattern is enhanced.

An exemplary embodiment of the method comprises forming a base layer, a first mask pattern and a second mask pattern in sequence on a substrate. The first mask pattern has identical features of a first width with inclined sidewalls. The second mask pattern has identical features of a second width. A smallest distance between any two adjacent inclined sidewalls of the first mask pattern is equal to the second width of the second mask pattern. The base layer is etched by using the first mask pattern as an etch mask to form first openings therein having the second width. A fill layer is formed covering the substrate and then the second mask pattern is removed to form second openings in the fill layer. The first mask pattern and the base layer are etched through the second openings to form third openings. Then, the fill layer and the first mask pattern are removed to form a pattern of the base layer having identical features of a third width, wherein the third width of the features of the base layer pattern is equal to the second width.

In an exemplary embodiment, a semiconductor device is provided. The semiconductor device comprises a substrate. A pattern of a base layer having identical features is formed on the substrate, wherein the features are spaced from one another by a pitch. A trench is formed between any two adjacent features and any two adjacent trenches have different depths.

A detailed description is given in the following embodiments with reference to the accompanying drawings.

### BRIEF DESCRIPTION OF DRAWINGS

The invention can be more fully understood by reading the subsequent detailed description and examples with references made to the accompanying drawings, wherein:

FIGS. 1A-1I show schematic cross sections of intermediate stages of fabricating a fine pattern of a semiconductor device according to an embodiment of the invention; and

FIGS. 2A-2J show schematic cross sections of intermediate stages of fabricating a fine pattern of a semiconductor device according to another embodiment of the invention.

### DETAILED DESCRIPTION OF INVENTION

The following description is of the best-contemplated mode of carrying out the invention. This description is made for the purpose of illustrating the general principles of the invention and should not be taken in a limiting sense. The scope of the invention is best determined by reference to the appended claims.

Exemplary embodiments of the invention provide methods for fabricating a fine pattern of a semiconductor device using an advanced double patterning process. According to the embodiments, the fine pattern is obtained without a spacer deposition process and without a spacer etching process as used in the conventional double patterning process. The fine pattern has identical features spaced from one another by a pitch equal to or less than a resolution limitation of a photolithography process for critical dimensions (CD) of the fine pattern of the semiconductor device. Further, according to the embodiments, the critical dimensions (CD) of the fine pattern are controlled accurately and CD uniformity of the fine pattern is better than the conventional double patterning processes.

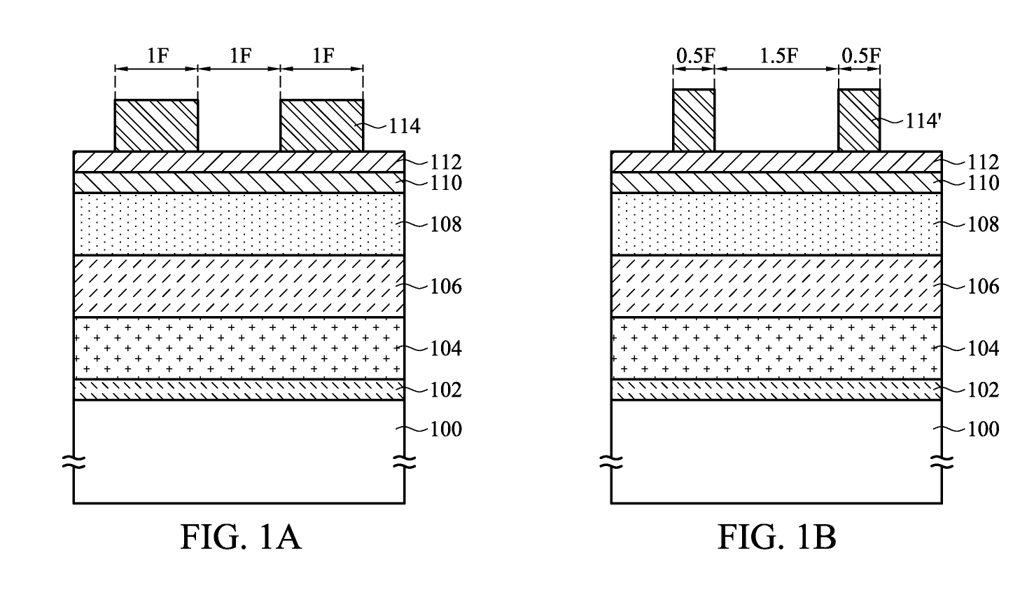

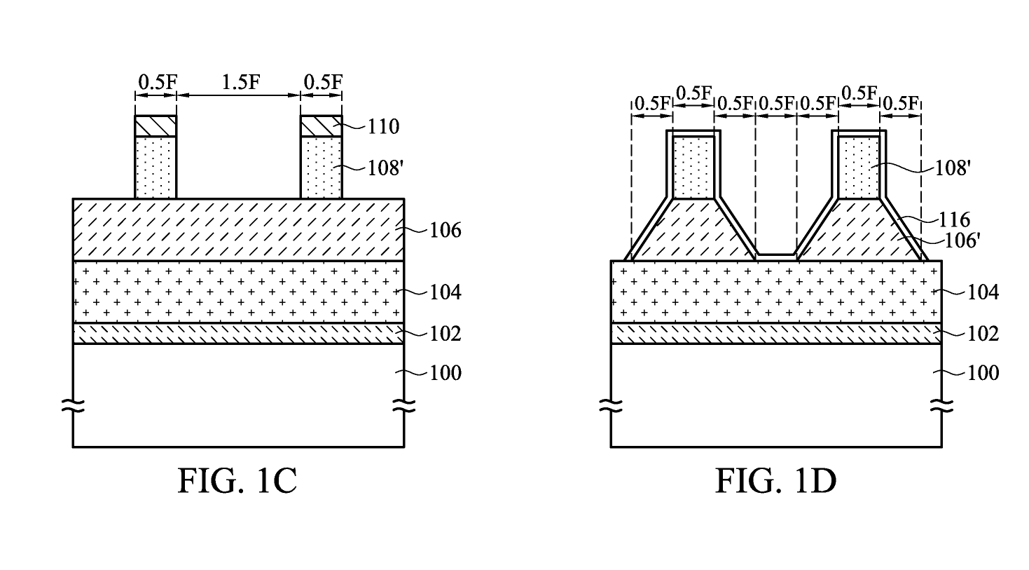

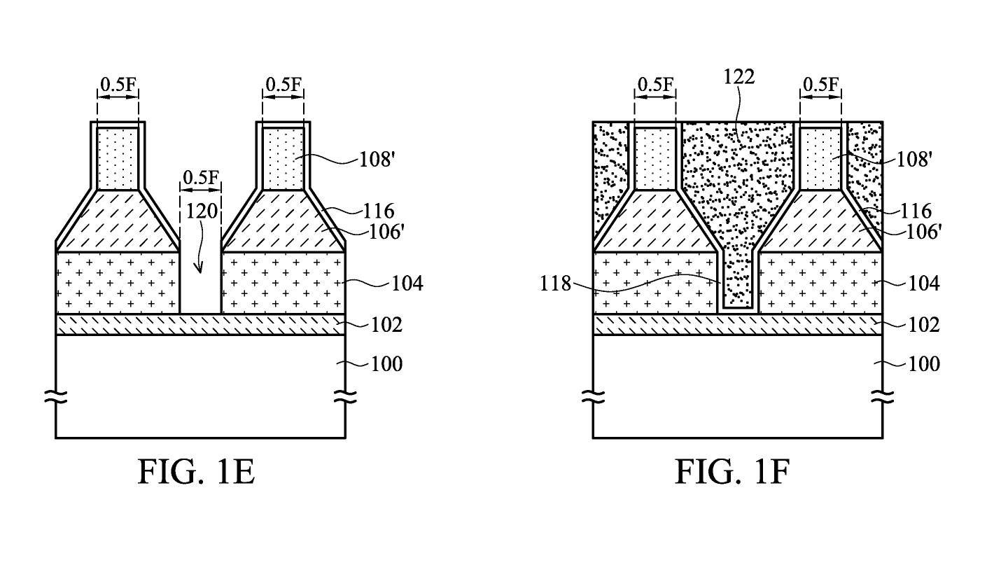

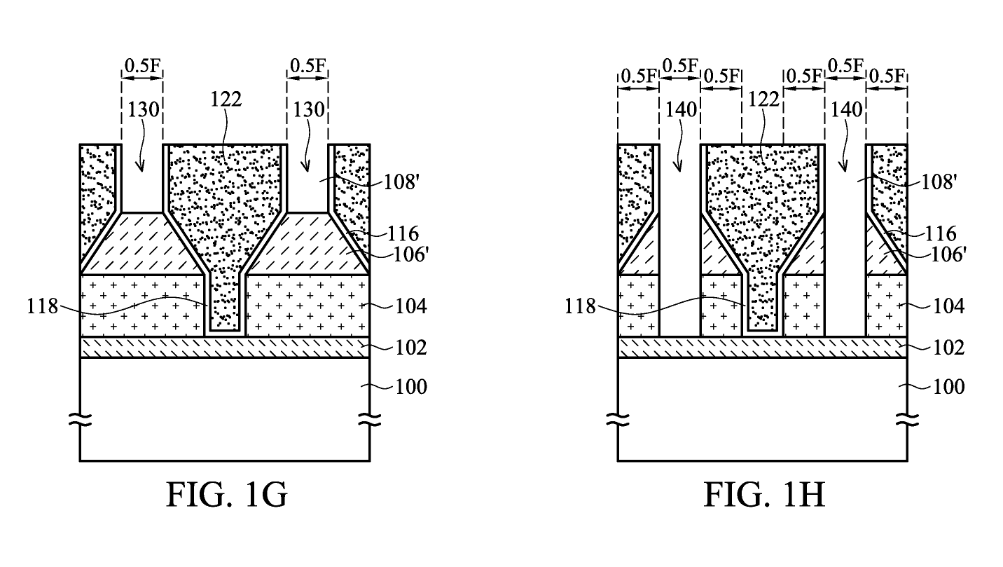

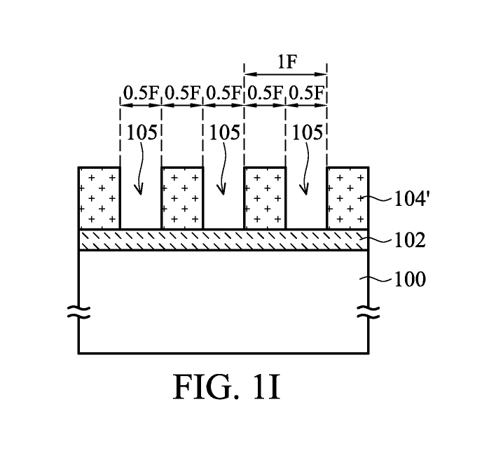

FIGS. 1A-1I show cross sections of intermediate stages of fabricating a semiconductor device according to an embodiment of the invention. Referring to FIG. 1A, first, a substrate 100 is provided. The substrate 100 may be a semiconductor substrate, a glass substrate, or a silicon-on-insulator (SOI) substrate. Then, an etch stop layer 102, a base layer 104, a first mask layer 106, a second mask layer 108, a dielectric anti-reflective coating (DARC) layer 110 and a bottom anti-reflective coating (BARC) layer 112 are formed on the substrate 100 in sequence, wherein the etch stop layer 102, the DARC layer 110 and the BARC layer 112 are optionally formed on the substrate. In an embodiment, the etch stop layer 102 may be formed of silicon nitride (SiN). The base layer 104 may be formed of polysilicon or any other suitable materials for forming a fine pattern of a semiconductor device. The first mask layer 106 may be a silicon oxide layer or a silicon nitride layer. The second mask layer 108 may be a silicon carbide layer. The DARC layer 110 and the BARC layer 112 may be formed of silicon oxynitride or other suitable inorganic materials. Then, a first photoresist pattern 114 is formed on the BARC layer 112 by a photolithography process. The first photoresist pattern 114 has identical features, with a width of 1 F, wherein 1 F is a resolution limitation of the photolithography process for a critical dimension (CD) of a fine pattern of a semiconductor device. A distance between two adjacent features of the first photoresist pattern 114 is also equal to 1 F.

Referring to FIG. 1B, the widths of the features of the first photoresist pattern 114 are trimmed from 1 F to 0.5 F, forming a second photoresist pattern 114′. In an embodiment, the first photoresist pattern 114 can be trimmed by a plasma etching process using an etchant of Cl₂ and O₂. The resulting second photoresist pattern 114′ has identical features, with a width of 0.5 F, and a distance between two adjacent features of the second photoresist pattern 114′ is equal to 1.5 F.

Referring to FIG. 1C, the DARC layer 110, the BARC layer 112 and the second mask layer 108 are etched using the second photoresist pattern 114′ as an etch mask. Then, a second mask pattern 108′ is formed on the first mask layer 106 and a portion of the DARC layer 110 is remaining on the second mask pattern 108′. The second mask pattern 108′ has the same pattern as the second photoresist pattern 114′. In other words, the second mask pattern 108′ has identical features, with a width of 0.5 F, and a distance between two adjacent features of the second mask pattern 108′ is equal to 1.5 F. In an embodiment, the DARC layer 110 and the BARC layer 112 may be etched by a dry etching process using an etchant of CF₄, CH₂F₂ and O₂. The second mask layer 108 may be etched by a dry etching process using an etchant of SO₂ and O₂. In an embodiment, the second mask layer 108 may have a thickness of about 200 nm.

Referring to FIG. 1D, the first mask layer 106 is etched using the second mask pattern 108′ as an etch mask to form a first mask pattern 106′ which exposes a portion of the base layer 104. As shown in FIG. 1D, from a cross section view, the first mask pattern 106′ has identical taper-shaped features, with inclined sidewalls. A top width of the taper-shaped feature is equal to 0.5 F and a bottom width thereof is equal to 1.5 F. The smallest distance between any two adjacent inclined sidewalls of the first mask pattern 106′ is equal to 0.5 F, i.e. the width of the features of the second mask pattern 108′. In an embodiment, the first mask layer 106 may be etched by a dry etching process using an etchant of CF₄, CH₂F₂ and O₂. In an embodiment, the first mask layer 106 may have a thickness of about 160-200 nm. During the step of etching the first mask layer 106, the portion of the DARC layer 110 remaining on the second mask pattern 108′ is also removed.

Next, a first liner layer 116 is conformally formed on the second mask pattern 108′, the inclined sidewalls of the first mask pattern 106′ and the exposed surface of the base layer 104. In an embodiment, the first liner layer 116 may be formed of TiN or other suitable materials by a deposition process. The first liner layer 116 can protect the second mask pattern 108′ and the first mask pattern 106′ from damage during subsequent processes.

Referring to FIG. 1E, a portion of the first liner layer 116 is removed to expose the underlying base layer 104. Then, the base layer 104 is etched using the first mask pattern 106′ as an etch mask to form openings 120 in the base layer 104 and the etch stop layer 102 is exposed. In an embodiment, the base layer 104 may be etched by a dry etching process using an etchant of NF₃. In an embodiment, an etch selectivity of the first mask layer 106 to the base layer 104 may be about 1:10. In this embodiment, because the etch stop layer 102 is formed on the substrate 100, the base layer 104 is etched until reaching the etch stop layer 102.

Referring to FIG. 1F, a second liner layer 118 is conformally formed on the sidewalls and the bottom of the openings 120. In an embodiment, the second liner layer 118 may be formed of TiN or other suitable materials by a deposition process. The material of the second liner layer 118 may be the same as or different to that of the first liner layer 116. Then, a fill layer 122 is formed covering the substrate 100 by blanket deposition. Next, a chemical mechanical polishing (CMP) process is performed on the fill layer 122 until reaching the first liner layer 116 on a top surface of the second mask pattern 108′. In an embodiment, the fill layer 122 may be formed of tungsten (W) or other suitable filling materials by a chemical vapor deposition (CVD) process. The spaces between the second mask pattern 108′, the spaces between the first mask pattern 106′ and the openings 120 are filled with the fill layer 122. In an embodiment, an etch selectivity of the second mask layer 108 to the fill layer 122 is greater than one.

Referring to FIG. 1G, a portion of the first liner layer 116 on the top surface of the second mask pattern 108′ is removed, and then the second mask pattern 108′ is removed to form openings 130 in the fill layer 122. In an embodiment, the second mask pattern 108′ may be removed by a stripping process or a dry etching process using an etchant of O₂.

Referring to FIG. 1H, then the first mask pattern 106′ and the base layer 104 are anisotropically etched through the openings 130 (as shown in FIG. 1G) until reaching the etch stop layer 102 to form openings 140. In an embodiment, the first mask pattern 106′ is etched by a dry etching process using an etchant of CF₄, CH₂F₂ and O₂. Then, the base layer 104 is etched by a dry etching process using an etchant of NF₃.

Referring to FIG. 1I, finally, the fill layer 122, the first liner layer 116, the second liner layer 118 and the first mask pattern 106′ are completely removed to leave a pattern of the base layer 104′ on the etch stop layer 102 overlying the substrate 100. In an embodiment, the fill layer 122, the first liner layer 116, the second liner layer 118 and the first mask pattern 106′ can be removed by a wet etching process. The resulting pattern of the base layer 104′ has identical features, with a width of 0.5 F which is equal to the width of the features of the second mask pattern 108′. The features of the pattern of the base layer 104′ are spaced from one another by a pitch of 1 F. In other words, a distance between any two adjacent features of the pattern of the base layer 104′ is equal to 0.5 F.

According to this embodiment, a fine pattern of a semiconductor device which has identical features, with a width of 0.5 F and spaced from one another by a pitch of 1 F is obtained. The width and the pitch of the features may be equal to or less than that formed by the conventional double patterning processes. In this embodiment, because the etch stop layer 102 is formed between the base layer 104 and the substrate 100, each trench formed between any two adjacent features of the pattern of the base layer 104′ has the same depth. Further, according to the embodiment, the fine pattern of the semiconductor device is fabricated by a spacer free and additional photomask free method.

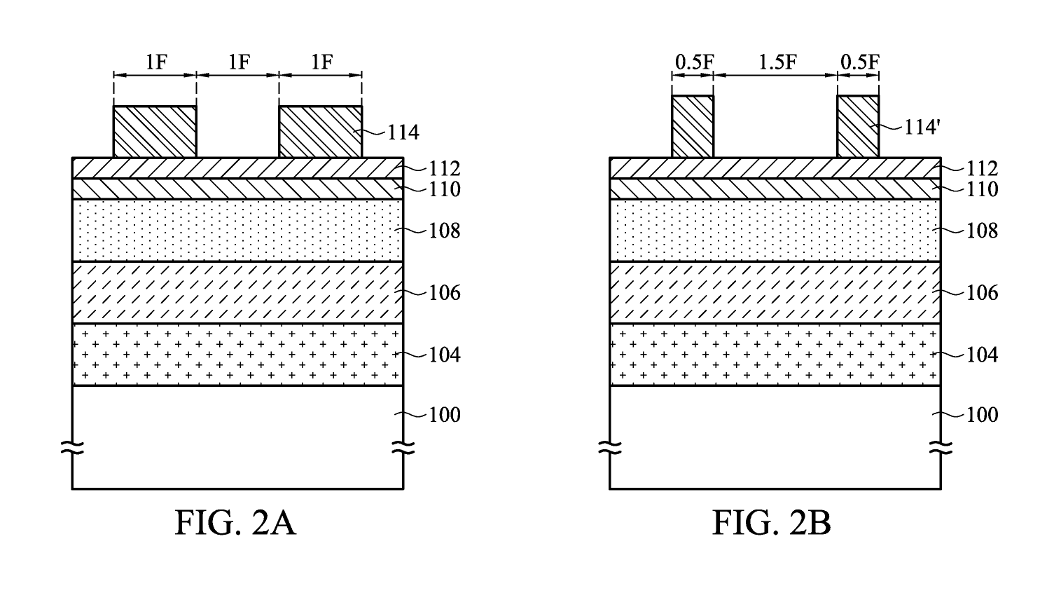

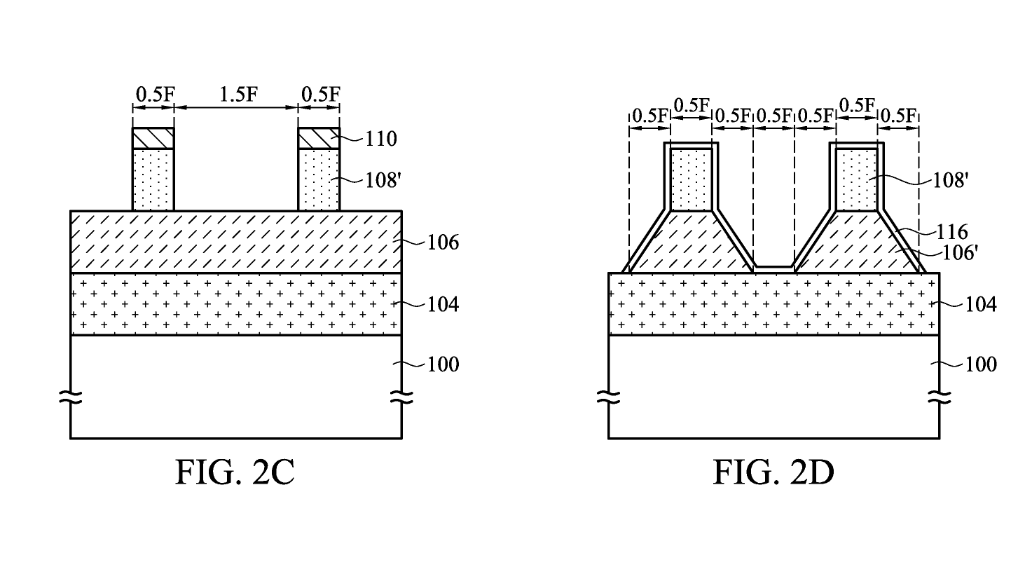

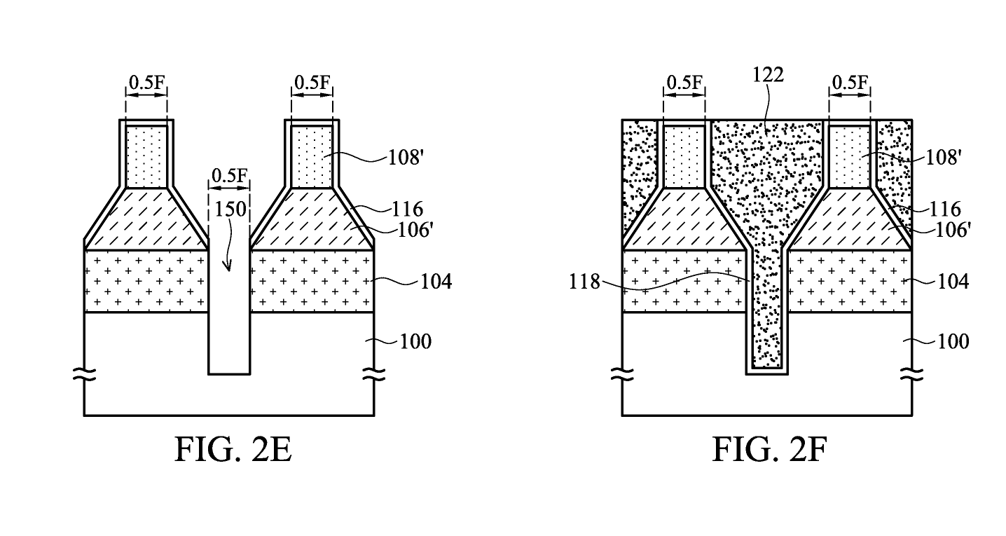

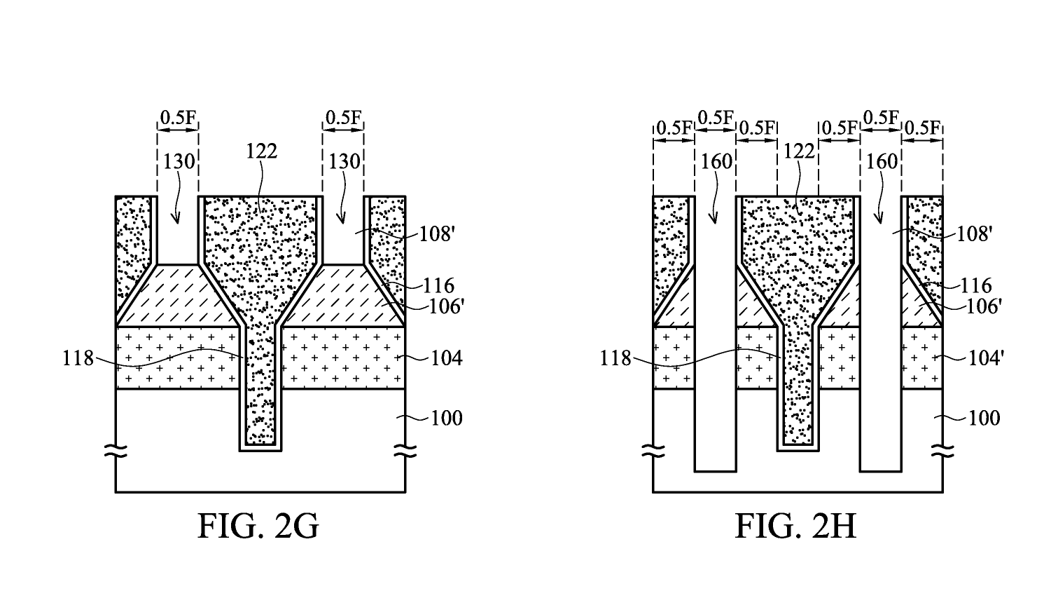

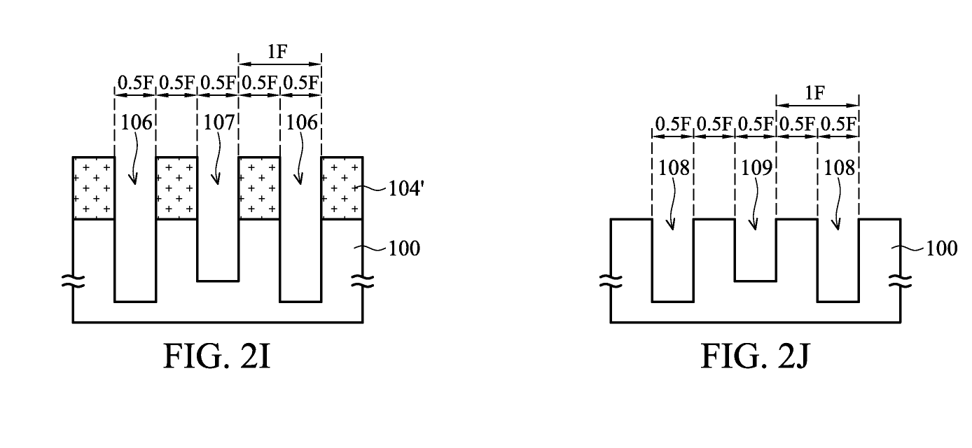

Next, referring to FIGS. 2A-2J, several cross sections of intermediate stages of fabricating a fine pattern of a semiconductor device according to another embodiment of the invention are shown. In this embodiment, there is no etch stop layer formed between the base layer 104 and the substrate 100. The materials of the layers formed on the substrate 100 and a part of the processes of forming the layers can be the same as the embodiment as described in FIGS. 1A-1I and are not repeated again herein for simplifying the description.

Referring to FIGS. 2A-2D, the materials and the processes of forming the base layer 104, the first mask layer 106, the second mask layer 108, the DARC layer 110, the BARC layer 112, and the photoresist patterns 114 and 114′ can be the same as the above mentioned descriptions of FIGS. 1A-1B. Further, the dimensions and the fabrication processes of the second mask pattern 108′ and the first mask pattern 106′ also can be the same as the above mentioned descriptions of FIGS. 1C-1D.

Then, referring to FIG. 2E, the base layer 104 is etched using the first mask pattern 106′ as an etch mask to form openings 150. In this embodiment, because there is no etch stop layer formed between the base layer 104 and the substrate 100, the base layer 104 may be etched until reaching a certain depth in the substrate 100.

Referring to FIG. 2F, a second liner layer 118 is conformally formed on the sidewalls and the bottom of the openings 150 (as shown in FIG. 2E). In an embodiment, the second liner layer 118 may be formed of TiN or other suitable materials by a deposition process. The material of the second liner layer 118 may be the same as that of the first liner layer 116. Then, a fill layer 122 is formed covering the substrate 100 by blanket deposition. Next, a chemical mechanical polishing (CMP) process is performed on the fill layer 122 to expose the first liner layer 116 disposed on the top surface of the second mask pattern 108′. In an embodiment, the fill layer 122 may be formed of tungsten (W) or other suitable filling materials by a chemical vapor deposition (CVD) process. The spaces between the second mask pattern 108′, the spaces between the first mask pattern 106′ and the openings 150 are filled with the fill layer 122. In an embodiment, an etch selectivity of the second mask layer 108 to the fill layer 122 is greater than one.

Referring to FIG. 2G, the first liner layer 116 on the top surface of the second mask pattern 108′ is removed, and then the second mask pattern 108′ is removed to form openings 130 in the fill layer 122. In an embodiment, the second mask pattern 108′ may be removed by a stripping process or a dry etching process using an etchant of O₂.

Referring to FIG. 2H, the first mask pattern 106′, the base layer 104 and a portion of the substrate 100 are anisotropically etched through the openings 130 (as shown in FIG. 2G). In an embodiment, the substrate 100 is etched until reaching a certain depth in the substrate 100 to form openings 160. The depth in the substrate 100 of the opening 160 is different from the depth of the opening 150 in the substrate 100 (as shown in FIG. 2E). In order to form deep trenches in the substrate 100, the fill layer 122 is a mask with high selectivity, for example a metal mask.

Referring to FIG. 2I, the fill layer 122, the first liner layer 116, the second liner layer 118 and the first mask pattern 106′ are completely removed to leave a pattern of the base layer 104′ on the substrate 100. In an embodiment, the first liner layer 116, the second liner layer 118 and the first mask pattern 106′ can be removed by a wet etching process. The resulting pattern of the base layer 104′ has identical features, with a width of 0.5 F. The features are spaced from one another by a pitch of 1 F. In other words, a distance between any two adjacent features of the pattern of the base layer 104′ is equal to 0.5 F. Moreover, according to this embodiment, a trench 107 formed between two adjacent features has a depth different to a depth of a trench 106 spaced from the trench 107. Therefore, a fine pattern of a semiconductor device having a plurality of trenches with different depths is obtained.

Then, referring to FIG. 2J, the pattern of the base layer 104′ on the substrate 100 is removed to leave the substrate 100 having a plurality of trenches 108 and 109 with different depths. These trenches 108 and 109 in the substrate 100 may be filled with an insulating material such as silicon nitrides or silicon oxides to form isolation structures (not shown) of different depths in the substrate 100. In addition, the isolation structures in the substrate 100 have identical widths of 0.5 F and are spaced from one another by a pitch of 1F.

Further, according to this embodiment, the fine pattern of the semiconductor device has identical features, with a width of 0.5 F and spaced from one another by a pitch of 1 F. The width and the pitch of the features may be equal to or less than that formed by the conventional double patterning processes. Similarly, the fine pattern of the semiconductor device is fabricated by a spacer free and additional photomask free method according to the embodiment of the invention.

According to the aforementioned embodiments, methods for fabricating a fine pattern of a semiconductor device are provided. The fine pattern has identical features spaced from one another by a pitch equal to or less than a resolution limitation of a photolithography process for a critical dimension (CD) of a pattern of a semiconductor device. The methods for fabricating the fine pattern are performed with spacer free and additional photomask free processes. Thus, enhancing the critical dimensions (CD) control and CD uniformity of the fine pattern. Moreover, the methods for fabricating a fine pattern of a semiconductor device can control the depths of the trenches between the features of the fine pattern.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A method for fabricating a semiconductor device, comprising:
forming a base layer, a first mask pattern having identical features of a first width with inclined sidewalls and a second mask pattern having identical features of a second width in sequence on a substrate, wherein a smallest distance between any two adjacent inclined sidewalls is equal to the second width;
etching the base layer by using the first mask pattern as an etch mask to form first openings of the second width;
forming a filling layer covering the substrate;
removing the second mask pattern to form second openings in the fill layer;
etching the first mask pattern and the base layer through the second openings to form third openings; and
removing the fill layer and the first mask pattern to form a pattern of the base layer having identical features of a third width, wherein the third width of the features of the base layer pattern is equal to the second width.

2. The method as claimed in claim 1, wherein the first width is a resolution limitation of a photolithography process for a critical dimension of the pattern of the base layer.

3. The method as claimed in claim 1, further comprising forming an etch stop layer between the base layer and the substrate.

4. The method as claimed in claim 3, wherein the step of etching the base layer to form the first openings is performed until reaching the etch stop layer.

5. The method as claimed in claim 3, wherein the step of etching the first mask pattern and the base layer to form the third openings is performed until reaching the etch stop layer.

6. The method as claimed in claim 3, wherein the pattern of the base layer has a trench between any two adjacent features, and each trench has the same depth.

7. The method as claimed in claim 1, wherein the step of etching the base layer to form the first openings is performed until reaching a first depth in the substrate.

8. The method as claimed in claim 7, wherein the step of etching the first mask pattern and the base layer to form the third openings is performed until reaching a second depth in the substrate.

9. The method as claimed in claim 8, wherein the first depth is different from the second depth.

10. The method as claimed in claim 9, wherein the base layer pattern has a trench between any two adjacent features, and any two adjacent trenches have different depths.

11. The method as claimed in claim 1, wherein the step of forming the first mask pattern and the second mask pattern comprises:
forming a first photoresist pattern having identical features of a width twice as the second width over the second mask layer;
trimming the first photoresist pattern to form a second photoresist pattern having identical features of a width, wherein the width of the second photoresist pattern is a half of the width of the first photoresist pattern;
etching a second mask layer by using the second photoresist pattern as an etch mask to form the second mask pattern; and
etching a first mask layer by using the second mask pattern as an etch mask to form the first mask pattern.

12. The method as claimed in claim 1, after the step of forming the first mask pattern, further comprising conformally forming a first liner layer on the inclined sidewalls of the first mask pattern, the second mask pattern and a portion of the base layer.

13. The method as claimed in claim 12, before the step of etching the base layer by using the first mask pattern as an etch mask, further comprising removing a portion of the first liner layer on the base layer.

14. The method as claimed in claim 12, after the step of etching the base layer by using the first mask pattern as an etch mask to form the first openings, further comprising conformally forming a second liner layer in the first openings.

15. The method as claimed in claim 14, during the step of removing the fill layer and the first mask pattern, further comprising removing the first liner layer and the second liner layer.

16. The method as claimed in claim 1, after the step of forming the fill layer covering the substrate, further comprising performing a chemical mechanical polishing (CMP) process on the fill layer.

17. A semiconductor device, comprising:
a substrate; and
a pattern of a base layer formed on the substrate, having identical features and a trench between any two adjacent features, wherein the features are spaced from one another by a pitch and any two adjacent trenches have different depths.

18. The semiconductor device as claimed in claim 17, wherein the pitch is a resolution limitation of a photolithography process for a critical dimension of the pattern of the base layer.

19. The semiconductor device as claimed in claim 17, wherein the trenches are embedded in the substrate.

20. The semiconductor device as claimed in claim 19, wherein any two adjacent trenches in the substrate have different depths, the trenches in the substrate have the same width and are spaced from one another by a pitch as twice as the width.
